(19) United States
(12) Patent Application Publication
(10) Pub. No.: US 2025/0098120 A1
(43) Pub. Date: Mar. 20, 2025

(54) COOLING MODULE

(71) Applicant: Fujitsu Limited, Kawasaki-shi (JP)

(72) Inventors: Hiroyuki Kubo, Kawasaki (JP); Yasuhisa Kanemaru, Fukuoka (JP)

(73) Assignee: Fujitsu Limited, Kawasaki-shi (JP)

(21) Appl. No.: 18/886,369

(22) Filed: Sep. 16, 2024

(30) Foreign Application Priority Data
Sep. 20, 2023 (JP) 2023-152313

(51) Int. Cl. H05K 7/20

(52) U.S. Cl. CPC H05K 7/20454; H05K 7/20409

(57) ABSTRACT

A cooling module includes a substrate, a heat radiation member fixed to the substrate with a gap between the heat radiation member and the substrate, a guide member that is disposed at a surface of the heat radiation member on a side of the substrate and that allows an electronic device to be inserted between the guide member and the substrate, a fixing mechanism that fixes the guide member to the heat radiation member so as to be movable in a direction in which the substrate and the guide member face each other, and a compressively deformable heat conductive member that is disposed between the heat radiation member and the guide member and overlaps with an opening provided in the guide member in a plan view.

### CROSS-REFERENCE TO RELATED APPLICATION

This application is based upon and claims the benefit of priority of the prior Japanese Patent Application No. 2023-152313, filed on Sep. 20, 2023, the entire contents of which are incorporated herein by reference.

### FIELD

The embodiments discussed herein are related to a cooling module.

### BACKGROUND

There is known a cooling module into and from which an electronic device is insertable and removable, having a configuration in which a heat transfer plate thermally coupled to a heat radiation member is pressed against the electronic device in a case where the electronic device is inserted. Furthermore, it is known to provide a heat conductive member having elasticity between a heat radiation member and an electronic device. Furthermore, there is known a configuration in which a heat radiation member is pressed against an electronic device by a compression spring.

Japanese Laid-open Patent Publication No. 2018-195633, Japanese Laid-open Patent Publication No. 2011-159704, Japanese Laid-open Patent Publication No. 2001-326492, U.S. Patent Application Publication No. 2021/0105914, U.S. Patent Application Publication No. 2021/0029855, and Japanese Laid-open Patent Publication No. 2005-57070 are disclosed as related art.

### SUMMARY

According to an aspect of the embodiments, a cooling module includes a substrate, a heat radiation member fixed to the substrate with a gap between the heat radiation member and the substrate, a guide member that is disposed at a surface of the heat radiation member on a side of the substrate and that allows an electronic device to be inserted between the guide member and the substrate, a fixing mechanism that fixes the guide member to the heat radiation member so as to be movable in a direction in which the substrate and the guide member face each other, and a compressively deformable heat conductive member that is disposed between the heat radiation member and the guide member and overlaps with an opening provided in the guide member in a plan view.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a cross-sectional view of a cooling module according to a first embodiment;

FIG. 2 is a plan view of a guide member in the first embodiment as viewed from a-Z direction;

FIGS. 3A to 3C are cross-sectional views illustrating a process of inserting an electronic device into the cooling module according to the first embodiment;

FIGS. 4A to 4C are cross-sectional views illustrating a process of removing the electronic device from the cooling module according to the first embodiment;

FIG. 5 is a cross-sectional view of a cooling module according to a modification of the first embodiment;

FIG. 6 is a cross-sectional view of a cooling module according to a second embodiment;

FIGS. 7A to 7C are cross-sectional views illustrating a process of inserting an electronic device into the cooling module according to the second embodiment;

FIG. 8A is a cross-sectional view of a cooling module according to a third embodiment;

FIG. 8B is a plan view of a heat conductive member in the third embodiment as viewed from a +Z direction;

FIGS. 9A to 9C are cross-sectional views illustrating a process of inserting an electronic device into the cooling module according to the third embodiment;

FIGS. 10A to 10C are plan views of a heat conductive member in a modification of the third embodiment as viewed from the +Z direction;

FIG. 11A is a cross-sectional view of a cooling module according to a fourth embodiment;

FIG. 11B is a plan view of a heat conductive member in the fourth embodiment as viewed from the −Z direction; and

FIGS. 12A to 12C are cross-sectional views illustrating a process of inserting an electronic device into the cooling module according to the fourth embodiment.

### DESCRIPTION OF EMBODIMENTS

In a cooling module into and from which an electronic device is insertable and removable, it is desired to improve cooling performance of the electronic device by suppressing thermal resistance between the electronic device and a heat radiation member.

In one aspect, an object is to improve cooling performance of an electronic device.

Hereinafter, embodiments will be described with reference to the drawings.

### First Embodiment

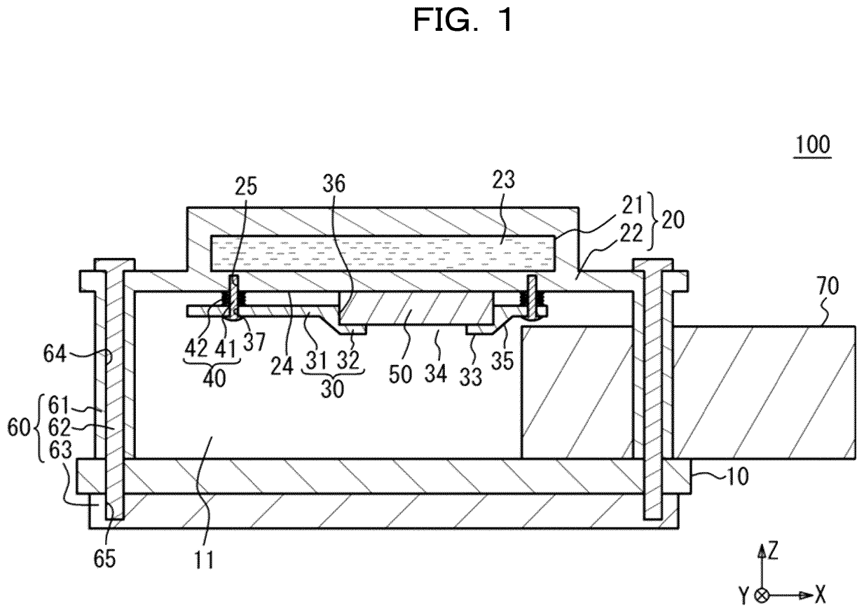

FIG. 1 is a cross-sectional view of a cooling module according to a first embodiment. As illustrated in FIG. 1, a cooling module 100 according to the first embodiment includes a substrate 10, a heat radiation member 20, a guide member 30, a fixing mechanism 40, a heat conductive member 50, and a fixing mechanism 60. A direction in which an electronic device 70 is inserted into and removed from the cooling module 100 is defined as an X direction, a direction orthogonal to the X direction in a planar direction of the substrate 10 is defined as a Y direction, and a direction in which the substrate 10 and the guide member 30 face each other with a gap 11 interposed therebetween is defined as a Z direction.

An upper surface of the substrate 10 is a flat surface. The substrate 10 may be an insulation member, a semiconductor member, or a metal member as long as the member has appropriate strength.

The heat radiation member 20 includes a refrigerant flow path 21 through which a refrigerant 23 such as a coolant flows, and a plate-like portion 22 having the refrigerant flow path 21 therein. The refrigerant flow path 21 and the plate-like portion 22 are integrated so as to allow heat transfer. The plate-like portion 22 is formed of, for example, a material having good thermal conductivity, such as copper. The heat radiation member 20 is disposed above the substrate 10 with the gap 11 between the heat radiation member 20 and the substrate 10. The refrigerant flow path 21 is provided at least in a range overlapping with the heat conductive member 50 in a plan view of the heat radiation member 20.

The heat radiation member 20 is fixed to the substrate 10 by the fixing mechanism 60. The fixing mechanism 60 includes a support portion 61, a screw 62, and a fixing plate 63. Although two fixing mechanisms 60 are illustrated in FIG. 1, the fixing mechanisms 60 are disposed at four corners of the substrate 10, for example. The support portion 61 extends from the plate-like portion 22 of the heat radiation member 20 toward the substrate 10, and is disposed between the plate-like portion 22 and the substrate 10, thereby supporting the heat radiation member 20 above the substrate 10. The support portion 61 may be integrally formed with the heat radiation member 20 or may be formed as a separate member. A through hole 64 penetrating in the Z direction is formed in the plate-like portion 22 of the heat radiation member 20, the support portion 61, and the substrate 10. The fixing plate 63 is overlapped with a surface of the substrate 10 on the opposite side of the heat radiation member 20. A screw hole 65 is formed in the fixing plate 63 at a position aligned with the through hole 64. The screw 62 is inserted from a side of the heat radiation member 20 of the through hole 64 toward the screw hole 65. A distal end portion of the screw 62 is screwed into the screw hole 65, whereby the heat radiation member 20 is fixed to the substrate 10.

The guide member 30 is disposed at a surface 24 of the heat radiation member 20 on a side of the substrate 10. The guide member 30 is a member having high rigidity formed of, for example, a metal material such as copper or iron. The guide member 30 has a Young's modulus larger than that of the heat conductive member 50. For example, the Young's modulus of the guide member 30 may be 100 times or more and 200 times or more the Young's modulus of the heat conductive member 50. The guide member 30 may have the Young's modulus smaller than that of, for example, the electronic device 70. The guide member 30 is disposed above the substrate 10, and has the gap 11 from the substrate 10. The electronic device 70 is inserted between the substrate 10 and the guide member 30. The electronic device 70 is, for example, a transceiver module or the like. Note that the guide member 30 may be formed of an insulating material or a semiconductor material.

The guide member 30 includes a main body portion 31 and a protrusion portion 32 protruding from the main body portion 31 toward the substrate 10. The main body portion 31 is formed in a plate shape, and is disposed to face the heat radiation member 20. The main body portion 31 is fixed to the heat radiation member 20 by the fixing mechanism 40. A top surface 33 of the protrusion portion 32 is formed in a flat shape, and is provided with an opening 34. Among side surfaces of the protrusion portion 32, at least a side surface on a side into which the electronic device 70 is inserted is a tapered inclined surface 35 that increases a thickness of the guide member 30 toward the opening 34.

The guide member 30 is provided with a recess portion 36 at a surface on the side of the heat radiation member 20. The recess portion 36 is provided in a range overlapping with the protrusion portion 32. The recess portion 36 is coupled to the opening 34 at a bottom portion. The recess portion 36 has a shape larger than the opening 34 in a plan view.

The fixing mechanism 40 fixes the guide member 30 to the heat radiation member 20 such that the guide member 30 is movable in the Z direction relative to the heat radiation member 20. The fixing mechanism 40 includes a screw 41 and a compression spring 42 provided around the screw 41 between the heat radiation member 20 and the guide member 30. For example, the screw 41 is inserted into a gap at a center of the compression spring 42. The screw 41 is a fixing member that fixes the guide member 30 to the heat radiation member 20, and the compression spring 42 is an energizing member that is provided between the guide member 30 and the heat radiation member 20 and energizes the guide member 30 toward the side of the substrate 10.

A through hole 37 into which the screw 41 is inserted is formed in the guide member 30. A screw hole 25 is formed in the heat radiation member 20 at a position aligned with the through hole 37. The screw 41 is inserted into the through hole 37 from the side of the substrate 10 toward the screw hole 25. Then, a distal end portion of the screw 41 is screwed into the screw hole 25, whereby the guide member 30 is fixed to the heat radiation member 20. Since the compression spring 42 is provided between the heat radiation member 20 and the guide member 30, the guide member 30 is movable in the Z direction relative to the heat radiation member 20.

The heat conductive member 50 is, for example, a member having elasticity, and is a thermal interface material (TIM). The heat conductive member 50 is, for example, a resin to which a heat conductive filler such as boron nitride (BN), aluminum nitride (AlN), or aluminum oxide (Al₂O₃) is added, and is, for example, rubber to which a heat conductive filler is added. A thickness of the heat conductive member 50 is, for example, about 1 mm to 2 mm. The heat conductive member 50 is disposed between the heat radiation member 20 and the guide member 30. The heat conductive member 50 is disposed between the heat radiation member 20 and the guide member 30 by being provided in the recess portion 36 of the guide member 30. In a state where the electronic device 70 is not inserted between the substrate 10 and the guide member 30, the heat conductive member 50 may be in contact with the heat radiation member 20 or may be away from the heat radiation member 20.

The heat conductive member 50 is provided to overlap with the opening 34 in a plan view. The heat conductive member 50 is exposed to the gap 11 through the opening 34. The heat conductive member 50 does not have to protrude into the opening 34 in the state where the electronic device 70 is not inserted between the substrate 10 and the guide member 30. The guide member 30 is movable in the Z direction relative to the heat radiation member 20 within a range in which, for example, the heat conductive member 50 is elastically deformed in the Z direction. The heat conductive member 50 is provided in a range overlapping with the refrigerant flow path 21 in a plan view of the heat radiation member 20.

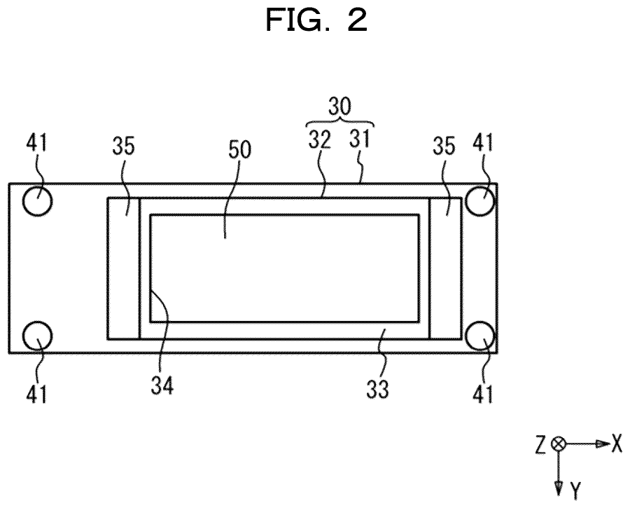

FIG. 2 is a plan view of the guide member in the first embodiment as viewed from a-Z direction. As illustrated in FIG. 2, the guide member 30 is fixed to the heat radiation member 20 by the screws 41 provided at the four corners. The opening 34 provided at the top surface 33 of the protrusion portion 32 of the guide member 30 has, for example, a rectangular shape in a plan view. The heat conductive member 50 has a shape larger than the opening 34 in a plan view, is provided to overlap with the opening 34, and is exposed from the opening 34. Note that the opening 34 is not limited to the rectangular shape in a plan view, and may have another shape such as a circular shape, an elliptical shape, or an oval shape.

As illustrated in FIG. 1, the electronic device 70 has a flat plate shape, and may be accommodated in the gap 11 and taken out from the gap 11 by being inserted into and removed from the gap 11 in the X direction. When the electronic device 70 is inserted into the gap 11 from the X direction, the heat conductive member 50 comes into contact with the electronic device 70 from the opening 34 as described in detail below.

### [Insertion and Removal of Electronic Device]

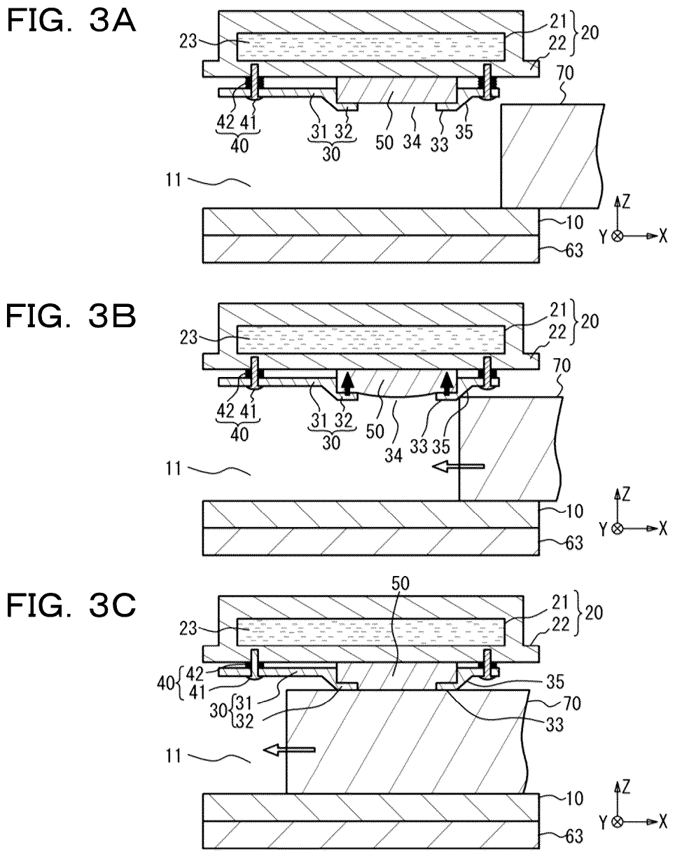

FIGS. 3A to 3C are cross-sectional views illustrating a process of inserting the electronic device into the cooling module according to the first embodiment. In FIGS. 3A to 3C, only a periphery of the guide member 30 is illustrated for clarity of the drawings (hereinafter, the same applies to similar drawings). As illustrated in FIG. 3A, before the electronic device 70 is inserted between the substrate 10 and the guide member 30, the heat conductive member 50 does not protrude to the opening 34, and is exposed to the gap 11 through the opening 34.

As illustrated in FIG. 3B, when the electronic device 70 is inserted between the substrate 10 and the guide member 30, the electronic device 70 comes into contact with the inclined surface 35 of the protrusion portion 32 of the guide member 30 and pushes up the guide member 30 in a +Z direction as indicated by black arrows. At this time, the compression spring 42 is contracted by being pressed between the heat radiation member 20 and the guide member 30. As the electronic device 70 pushes up the guide member 30 in the +Z direction, the heat conductive member 50 is pushed by the guide member 30, and is compressively deformed (for example, elastically compressed) between the heat radiation member 20 and the guide member 30. A part of the heat conductive member 50 enters the opening 34 by being pushed by the guide member 30. Furthermore, when the electronic device 70 comes into contact with the inclined surface 35 of the protrusion portion 32 of the guide member 30, a force in a-X direction is applied to the guide member 30 by the electronic device 70. However, since the guide member 30 is fixed to the heat radiation member 20 by the fixing mechanism 40, movement in the −X direction relative to the heat radiation member 20 is suppressed even when the force in the −X direction is applied.

As illustrated in FIG. 3C, when the electronic device 70 is further inserted and reaches the top surface 33 of the protrusion portion 32 of the guide member 30, the elastically compressed heat conductive member 50 comes into contact with the electronic device 70 at the opening 34. Since the heat conductive member 50 is elastically compressed, the electronic device 70 is pressed by the heat conductive member 50. Therefore, the heat conductive member 50 comes into contact with the electronic device 70 in a state where the heat conductive member 50 presses the electronic device 70.

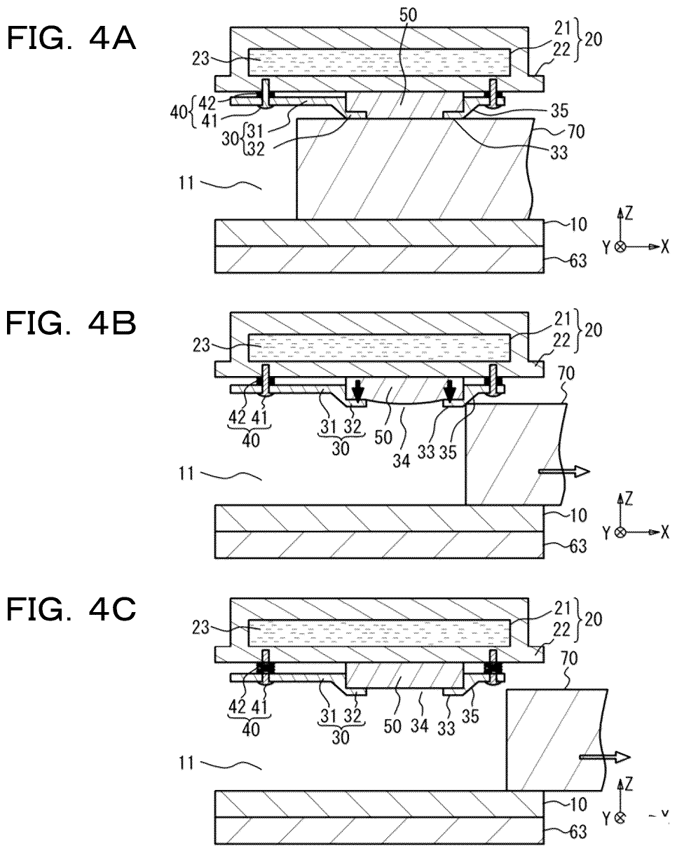

FIGS. 4A to 4C are cross-sectional views illustrating a process of removing the electronic device from the cooling module according to the first embodiment. As illustrated in FIG. 4A, in a state where the electronic device 70 is inserted between the substrate 10 and the guide member 30, the heat conductive member 50 is in contact with the electronic device 70 in a state of being pressed against the electronic device 70. Furthermore, the compression spring 42 is contracted by being pressed by the guide member 30 between the heat radiation member 20 and the guide member 30.

As illustrated in FIG. 4B, as the electronic device 70 is removed from between the substrate 10 and the guide member 30, the guide member 30 is lowered in the −Z direction as indicated by black arrows while the inclined surface 35 of the protrusion portion 32 comes into contact with the electronic device 70. In addition to being lowered in the −Z direction by its own weight, the guide member 30 is lowered in the −Z direction also by a repulsive force of the compression spring 42. Since the electronic device 70 is removed while being in contact with the top surface 33 of the protrusion portion 32 of the guide member 30, a force in a +X direction is applied to the guide member 30 by a frictional force with the electronic device 70. However, since the guide member 30 is fixed to the heat radiation member 20 by the fixing mechanism 40, movement in the +X direction relative to the heat radiation member 20 is suppressed even when the force in the +X direction is applied.

As illustrated in FIG. 4C, when the electronic device 70 is removed from between the substrate 10 and the guide member 30, the guide member 30 returns to an initial position. As a result, the heat conductive member 50 is released from the elastic compression, and is exposed to the gap 11 through the opening 34 without protruding to the opening 34. Note that, in the above description, the case where the compressive deformation of the heat conductive member 50 due to the insertion and removal of the electronic device 70 is elastic deformation has been described as an example, but the compressive deformation may be plastic deformation.

As described above, according to the first embodiment, as illustrated in FIG. 1, the heat radiation member 20 is fixed to the substrate 10 with the gap 11 between the heat radiation member 20 and the substrate 10. The guide member 30 is disposed at the surface 24 of the heat radiation member 20 on the side of the substrate 10, and the electronic device 70 is inserted between the substrate 10 and the guide member 30. The fixing mechanism 40 fixes the guide member 30 to the heat radiation member 20 such that the guide member 30 is movable in the Z direction. The compressively deformable heat conductive member 50 is disposed between the heat radiation member 20 and the guide member 30, and overlaps with the opening 34 provided in the guide member 30 in a plan view. With such a configuration, when the electronic device 70 is inserted between the substrate 10 and the guide member 30, the heat conductive member 50 comes into contact with the electronic device 70 at the opening 34 of the guide member 30. As a result, the electronic device 70 is thermally coupled to the heat radiation member 20 via the heat conductive member 50. For this reason, for example, thermal resistance is reduced as compared with a case where the electronic device is thermally coupled to the heat radiation member via the heat transfer member and the heat conductive member as in Japanese Laid-open Patent Publication No. 2018-195633. For example, the thermal resistance of the heat transfer member is eliminated, and the thermal resistance of the electronic device and the heat transfer member replaces the thermal resistance of the electronic device and the heat conductive member, so that the thermal resistance is reduced. Therefore, cooling performance of the electronic device 70 may be improved. Furthermore, the guide member 30 is fixed to the heat radiation member 20 by the fixing mechanism 40. For this reason, it is possible to suppress unintended movement and deformation of the guide member 30 and the heat conductive member 50 disposed between the guide member 30 and the heat radiation member 20 at the time of insertion and removal of the electronic device 70.

Furthermore, in the first embodiment, the guide member 30 has the protrusion portion 32 protruding toward the side of the substrate 10. The side surface of the protrusion portion 32 on the side into which the electronic device 70 is inserted is the inclined surface 35. The opening 34 provided in the guide member 30 is provided at the top surface 33 of the protrusion portion 32. As a result, when the electronic device 70 is inserted between the substrate 10 and the guide member 30, the guide member 30 is easily moved in the +Z direction by being pushed by the electronic device 70. As a result, the heat conductive member 50 easily comes into contact with the electronic device 70 from the opening 34 of the guide member 30.

Furthermore, in the first embodiment, the guide member 30 has the recess portion 36 coupled to the opening 34 at the surface on the side of the heat radiation member 20. The heat conductive member 50 is provided in the recess portion 36 and overlaps with the opening 34. As a result, unintended movement and deformation of the heat conductive member 50 at the time of insertion and removal of the electronic device 70 may be effectively suppressed.

Furthermore, in the first embodiment, as illustrated in FIGS. 3A to 4C, the guide member 30 is pushed up toward the side of the heat radiation member 20 by the electronic device 70 inserted between the substrate 10 and the guide member 30 coming into contact with the guide member 30. The heat conductive member 50 is compressively deformed when the guide member 30 is pushed up toward the side of the heat radiation member 20. As a result, the heat conductive member 50 easily comes into contact with the electronic device 70 from the opening 34 of the guide member 30.

Furthermore, in the first embodiment, the fixing mechanism 40 includes the screw 41 (fixing member) that fixes the guide member 30 to the heat radiation member 20, and the compression spring 42 (energizing member) that energizes the guide member 30 toward the side of the substrate 10. As a result, as illustrated in FIGS. 4A to 4C, when the electronic device 70 is removed from between the substrate 10 and the guide member 30, the guide member 30 is energized by the compression spring 42 and easily returns to the state before the electronic device 70 is inserted.

Furthermore, in the first embodiment, the heat conductive member 50 is rubber to which a heat conductive filler is added. As a result, in a case where the heat conductive member 50 is pushed by the guide member 30, a part of the heat conductive member 50 easily enters the opening 34 of the guide member 30. Therefore, the heat conductive member 50 easily comes into contact with the electronic device 70 from the opening 34 of the guide member 30.

Note that, in the first embodiment, it is sufficient that the heat conductive member 50 overlaps with the opening 34 over a maximum dimension in the X direction. As a result, insertion of the electronic device 70 is not hindered. Moreover, it is also avoided that a position of the heat conductive member 50 is shifted due to the insertion and removal of the electronic device 70. Therefore, the entire surface of the opening 34 does not need to overlap with the heat conductive member 50, and a gap may be provided in the Y direction.

### [Modification]

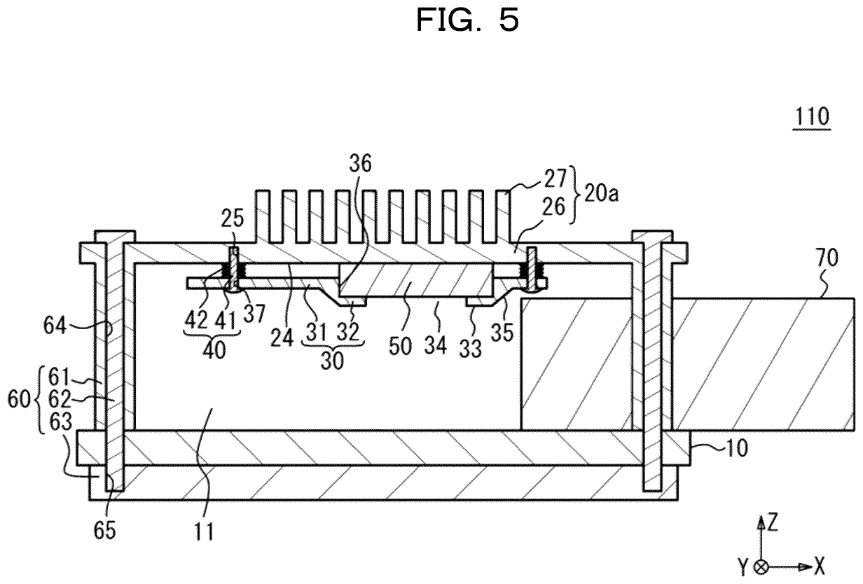

FIG. 5 is a cross-sectional view of a cooling module according to a modification of the first embodiment. As illustrated in FIG. 5, a cooling module 110 according to the modification of the first embodiment includes a heat radiation member 20a including a plate-like portion 26 and a plurality of heat dissipation fins 27 instead of the heat radiation member 20. The heat dissipation fins 27 extend from the plate-like portion 26 in the +Z direction. Other configurations are the same as those of the first embodiment, so description thereof will be omitted.

### Second Embodiment

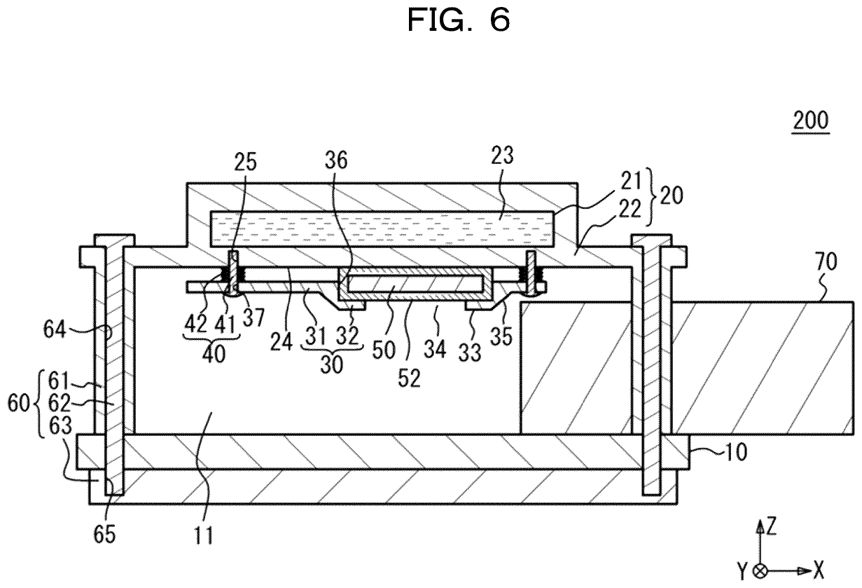

FIG. 6 is a cross-sectional view of a cooling module according to a second embodiment. As illustrated in FIG. 6, in a cooling module 200 according to the second embodiment, a coating film 52 is provided to cover a heat conductive member 50. The coating film 52 is provided to completely cover the heat conductive member 50, for example. The coating film 52 is, for example, a polyethylene terephthalate (PET) film, a polytetrafluoroethylene (PTFE) film, or a metal film such as stainless steel film. A thickness of the coating film 52 is, for example, about 10 μm to 50 μm. Other configurations are the same as those of the first embodiment, so description thereof will be omitted.

### [Insertion and Removal of Electronic Device]

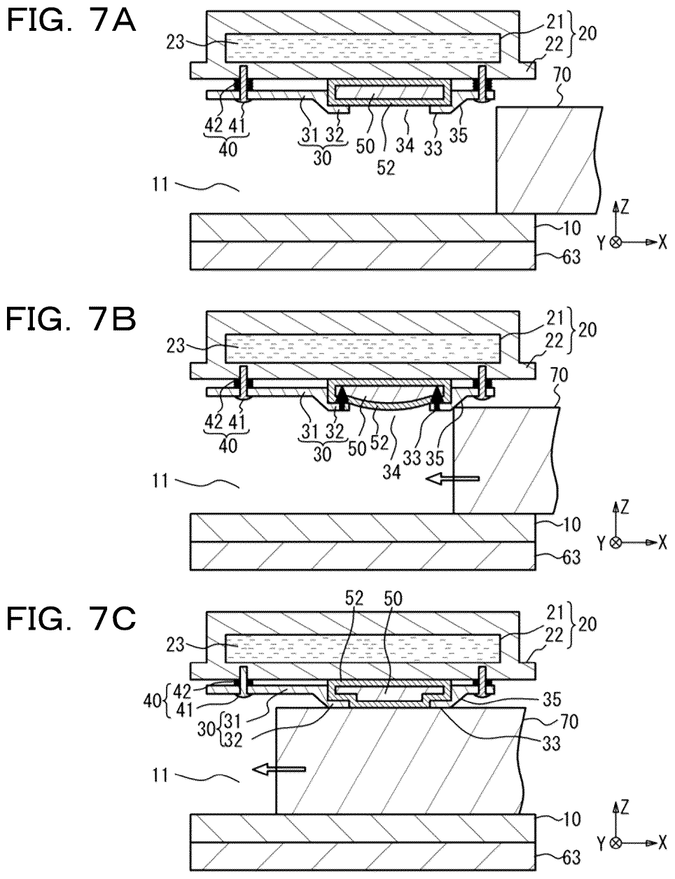

FIGS. 7A to 7C are cross-sectional views illustrating a process of inserting an electronic device into the cooling module according to the second embodiment. As illustrated in FIG. 7A, before an electronic device 70 is inserted between a substrate 10 and a guide member 30, the heat conductive member 50 and the coating film 52 do not protrude to an opening 34. Since the coating film 52 is provided to cover the heat conductive member 50, the coating film 52 is exposed to a gap 11 through the opening 34.

As illustrated in FIG. 7B, when the electronic device 70 is inserted between the substrate 10 and the guide member 30, as in the first embodiment, the electronic device 70 comes into contact with an inclined surface 35 of a protrusion portion 32 of the guide member 30 and pushes up the guide member 30 in the +Z direction. As the electronic device 70 pushes up the guide member 30 in the +Z direction, the heat conductive member 50 is pushed by the guide member 30, and is, for example, elastically compressed between a heat radiation member 20 and the guide member 30. The thickness of the coating film 52 hardly changes. A part of the heat conductive member 50 and the coating film 52 enters the opening 34 by being pushed by the guide member 30.

As illustrated in FIG. 7C, when the electronic device 70 is further inserted and reaches a top surface 33 of the protrusion portion 32 of the guide member 30, the coating film 52 is exposed from the opening 34 of the guide member 30 by the elastically compressed heat conductive member 50. As a result, the heat conductive member 50 comes into contact with the electronic device 70 via the coating film 52. Since the heat conductive member 50 is elastically compressed, the electronic device 70 is pressed by the heat conductive member 50. Therefore, the heat conductive member 50 comes into contact with the electronic device 70 in a state where the heat conductive member 50 presses the electronic device 70 via the coating film 52.

A process of removing the electronic device 70 from the cooling module 200 according to the second embodiment follows the process opposite to that of FIGS. 7A to 7C similarly to the removal of the electronic device 70 illustrated in FIGS. 4A to 4C, and thus description thereof will be omitted.

According to the second embodiment, the heat conductive member 50 is covered with the coating film 52. In a case where the heat conductive member 50 is not covered with the coating film 52, when the heat conductive member 50 is pushed by the guide member 30, deformation in the X direction and the Y direction may occur in the heat conductive member 50 in addition to deformation in the Z direction. However, since the heat conductive member 50 is covered with the coating film 52, it is possible to suppress deformation of the heat conductive member 50 in the X direction and the Y direction. Therefore, in a case where the heat conductive member 50 is pushed by the guide member 30, a part of the heat conductive member 50 and the coating film 52 easily enters the opening 34.

Furthermore, in the second embodiment, the heat conductive member 50 is rubber to which a heat conductive filler is added. In this case, at the time of insertion and removal of the electronic device 70, the electronic device 70 and the heat conductive member 50 come into contact with each other, so that wrinkles may be generated in the heat conductive member 50. By using a polyethylene terephthalate film, a polytetrafluoroethylene film, or a stainless steel film as the coating film 52 covering the heat conductive member 50, sliding performance between the electronic device 70 and the coating film 52 is improved, and friction is reduced. For this reason, it is possible to suppress generation of wrinkles in the heat conductive member 50 and the coating film 52.

### Third Embodiment

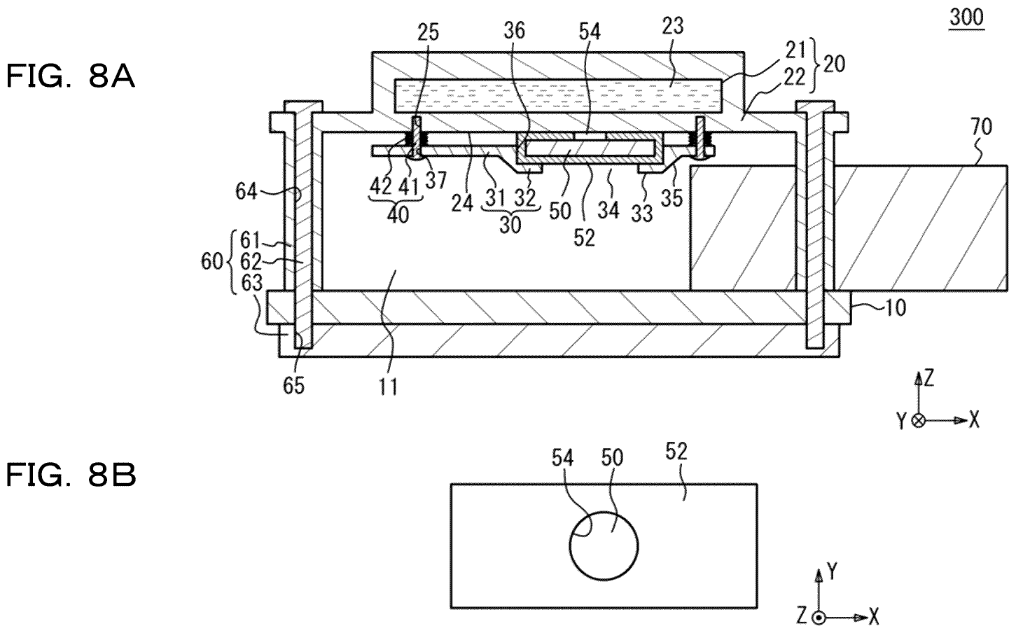

FIG. 8A is a cross-sectional view of a cooling module according to a third embodiment, and FIG. 8B is a plan view of a heat conductive member in the third embodiment as viewed from the +Z direction. As illustrated in FIGS. 8A and 8B, in a cooling module 300 according to the third embodiment, a coating film 52 is provided to cover a heat conductive member 50, as in the second embodiment. A difference from the second embodiment is that the coating film 52 has an opening 54 in a surface of the heat conductive member 50 on a side of a heat radiation member 20. The opening 54 has, for example, a circular shape in a plan view. Other configurations are the same as those of the first embodiment, so description thereof will be omitted.

### [Insertion and Removal of Electronic Device]

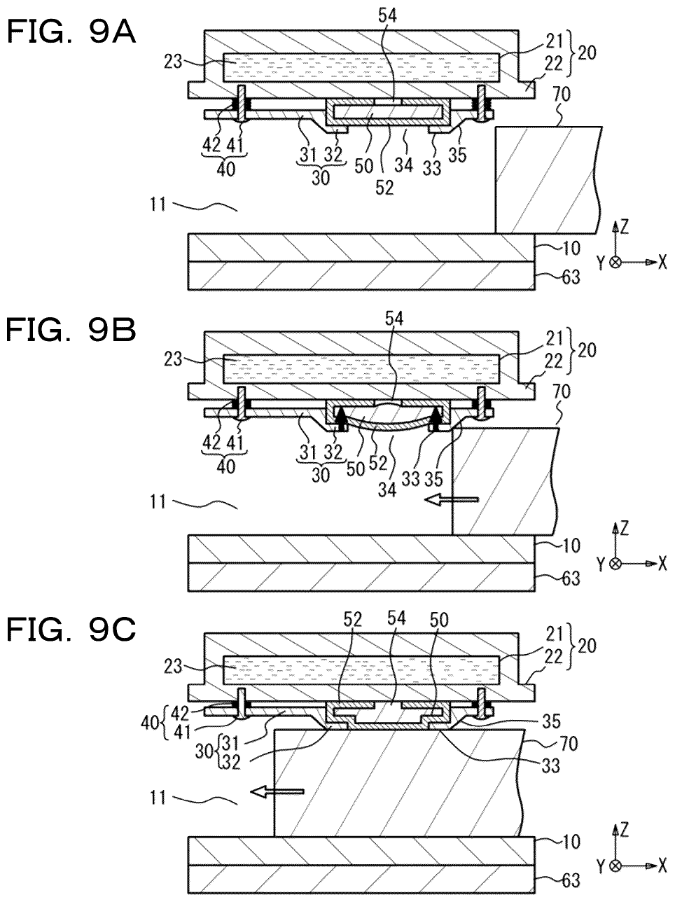

FIGS. 9A to 9C are cross-sectional views illustrating a process of inserting an electronic device into the cooling module according to the third embodiment. As illustrated in FIG. 9A, before an electronic device 70 is inserted between a substrate 10 and a guide member 30, the heat conductive member 50 and the coating film 52 do not protrude to an opening 34 of the guide member 30. Since the coating film 52 is provided to cover the heat conductive member 50, the coating film 52 is exposed to a gap 11 through the opening 34 of the guide member 30. Furthermore, the coating film 52 exists between the heat conductive member 50 and the heat radiation member 20.

As illustrated in FIG. 9B, when the electronic device 70 is inserted between the substrate 10 and the guide member 30, as in the first embodiment, the electronic device 70 comes into contact with an inclined surface 35 of a protrusion portion 32 of the guide member 30 and pushes up the guide member 30 in the +Z direction. As the electronic device 70 pushes up the guide member 30 in the +Z direction, the heat conductive member 50 is pushed by the guide member 30, and is, for example, elastically compressed between a heat radiation member 20 and the guide member 30. A thickness of the coating film 52 hardly changes. A part of the heat conductive member 50 and the coating film 52 enters the opening 34 of the guide member 30 by being pushed by the guide member 30. Furthermore, since the opening 54 is provided in the coating film 52, the heat conductive member 50 enters the opening 54.

As illustrated in FIG. 9C, when the electronic device 70 is further inserted and reaches a top surface 33 of the protrusion portion 32 of the guide member 30, the coating film 52 is exposed from the opening 34 of the guide member 30 by the elastically compressed heat conductive member 50. As a result, the heat conductive member 50 comes into contact with the electronic device 70 via the coating film 52. Since the heat conductive member 50 is elastically compressed, the electronic device 70 is pressed by the heat conductive member 50. Therefore, the heat conductive member 50 comes into contact with the electronic device 70 in a state where the heat conductive member 50 presses the electronic device 70 via the coating film 52. Furthermore, the heat conductive member 50 is exposed from the opening 54 of the coating film 52, and comes into contact with the heat radiation member 20 at the opening 54.

A process of removing the electronic device 70 from the cooling module 300 according to the third embodiment follows the process opposite to that of FIGS. 9A to 9C similarly to the removal of the electronic device 70 illustrated in FIGS. 4A to 4C, and thus description thereof will be omitted.

### [Modification]

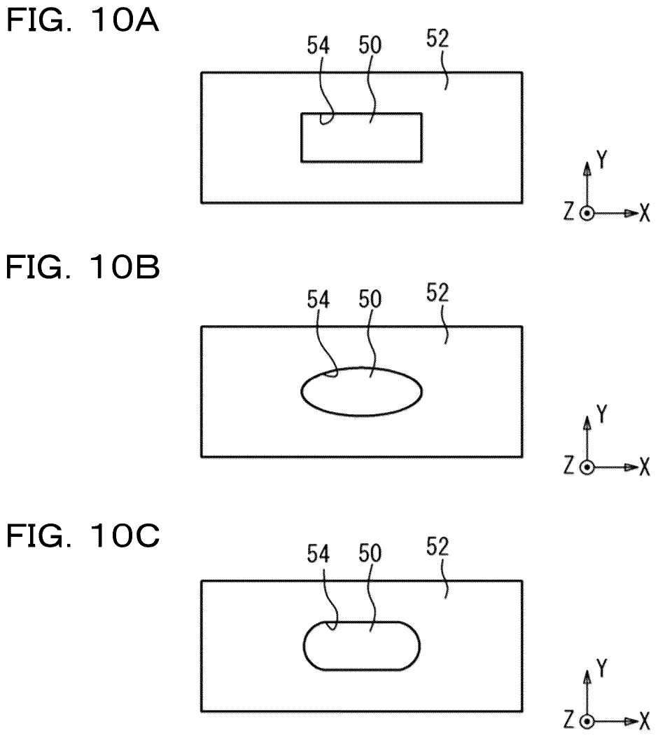

FIGS. 10A to 10C are plan views of a heat conductive member in a modification of the third embodiment as viewed from the +Z direction. An opening 54 provided in a coating film 52 may have a rectangular shape as illustrated in FIG. 10A, an elliptical shape as illustrated in FIG. 10B, or an oval shape as illustrated in FIG. 10C in a plan view. In this manner, the opening 54 may have various shapes. Furthermore, the number of the openings 54 to be provided is not limited to one, and a plurality of the openings 54 may be provided.

According to the third embodiment, since the coating film 52 covering the heat conductive member 50 is provided, as in the second embodiment, deformation of the heat conductive member 50 in the X and Y directions is suppressed. Therefore, a part of the heat conductive member 50 and the coating film 52 easily enters the opening 34 of the guide member 30. The opening 54 is provided in the portion of the coating film 52 positioned at the surface of the heat conductive member 50 on the side of the heat radiation member 20. For this reason, as illustrated in FIGS. 9A to 9C, when the electronic device 70 is inserted, the heat conductive member 50 comes into contact with the heat radiation member 20 at the opening 54. Therefore, cooling performance of the electronic device 70 may be improved as compared with that in the second embodiment.

A size of the opening 54 provided in the coating film 52 is preferably 20% or more, more preferably 30% or more, still more preferably 40% or more of an area of the surface of the heat conductive member 50 on the side of the heat radiation member 20 from a viewpoint of bringing the heat conductive member 50 into contact with the heat radiation member 20. On the other hand, when the opening 54 is too large, the effect of suppressing deformation of the heat conductive member 50 in the X and Y directions is weakened. Therefore, the size of the opening 54 is preferably 70% or less, more preferably 60% or less, still more preferably 50% or less of the area of the surface of the heat conductive member 50 on the side of the heat radiation member 20.

### Fourth Embodiment

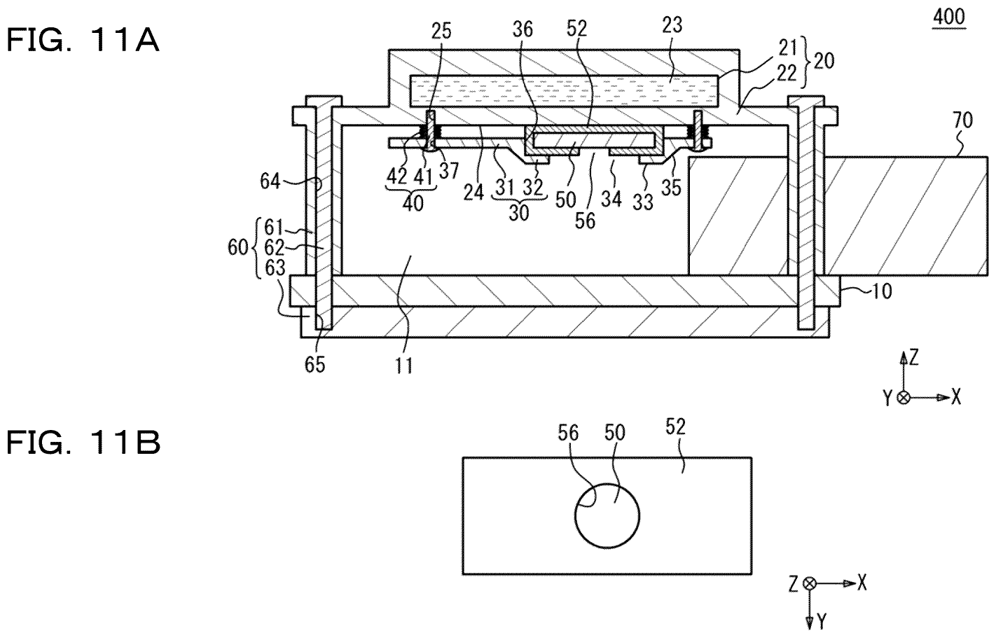

FIG. 11A is a cross-sectional view of a cooling module according to a fourth embodiment, and FIG. 11B is a plan view of a heat conductive member in the fourth embodiment as viewed from the −Z direction. As illustrated in FIGS. 11A and 11B, in a cooling module 400 according to the fourth embodiment, a coating film 52 is provided to cover a heat conductive member 50, as in the second embodiment. A difference from the second embodiment is that the coating film 52 has an opening 56 in a surface of the heat conductive member 50 on a side of a substrate 10. The opening 56 has, for example, a circular shape in a plan view. Other configurations are the same as those of the first embodiment, so description thereof will be omitted.

### [Insertion and Removal of Electronic Device]

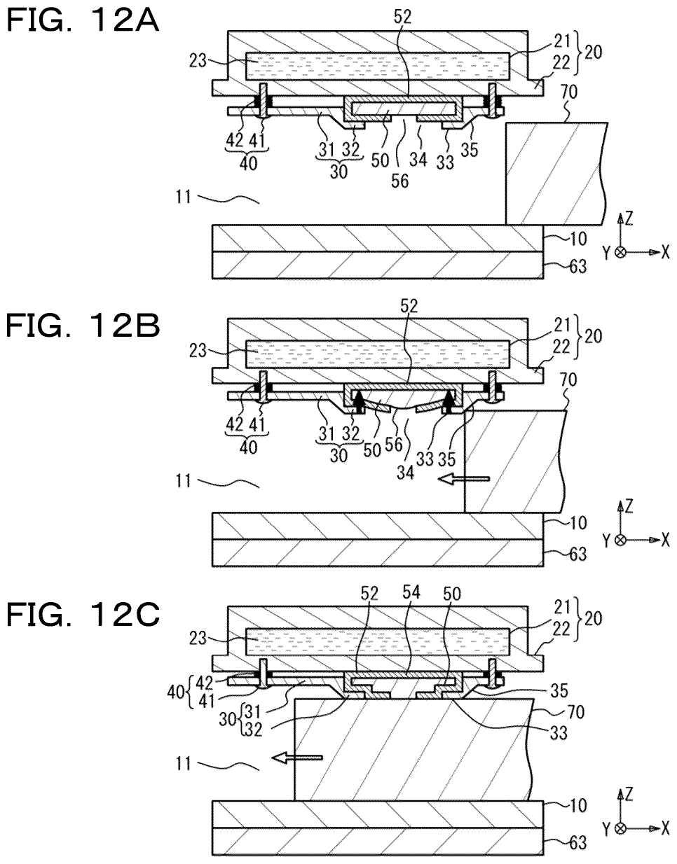

FIGS. 12A to 12C are cross-sectional views illustrating a process of inserting an electronic device into the cooling module according to the fourth embodiment. As illustrated in FIG. 12A, before an electronic device 70 is inserted between the substrate 10 and a guide member 30, the heat conductive member 50 and the coating film 52 do not protrude to an opening 34 of the guide member 30. The heat conductive member 50 is exposed to a gap 11 through the opening 56 of the coating film 52 and the opening 34 of the guide member 30, and the coating film 52 is exposed to the gap 11 through the opening 34 of the guide member 30. The coating film 52 exists between the heat conductive member 50 and the heat radiation member 20.

As illustrated in FIG. 12B, when the electronic device 70 is inserted between the substrate 10 and the guide member 30, as in the first embodiment, the electronic device 70 comes into contact with an inclined surface 35 of a protrusion portion 32 of the guide member 30 and pushes up the guide member 30 in the +Z direction. As the electronic device 70 pushes up the guide member 30 in the +Z direction, the heat conductive member 50 is pushed by the guide member 30, and is, for example, elastically compressed between a heat radiation member 20 and the guide member 30. A part of the heat conductive member 50 and the coating film 52 enters the opening 34 of the guide member 30 by being pushed by the guide member 30. Since the opening 56 is provided in the coating film 52, the heat conductive member 50 also enters the opening 56. A thickness of the coating film 52 hardly changes.

As illustrated in FIG. 12C, when the electronic device 70 is further inserted and reaches a top surface 33 of the protrusion portion 32 of the guide member 30, the coating film 52 is exposed from the opening 34 of the guide member 30 by the elastically compressed heat conductive member 50. Furthermore, the heat conductive member 50 is exposed from the opening 56 of the coating film 52. As a result, the coating film 52 comes into contact with the electronic device 70, and the heat conductive member 50 comes into contact with the electronic device 70 at the opening 56 of the coating film 52. Since the heat conductive member 50 is elastically compressed, the electronic device 70 is pressed by the heat conductive member 50.

A process of removing the electronic device 70 from the cooling module 400 according to the fourth embodiment follows the process opposite to that of FIGS. 12A to 12C similarly to the removal of the electronic device 70 illustrated in FIGS. 4A to 4C, and thus description thereof will be omitted.

Note that, similarly to the opening 54 provided in the coating film 52 in the third embodiment, the opening 56 provided in the coating film 52 is not limited to the circular shape in a plan view, and may have another shape such as a rectangular shape, an elliptical shape, or an oval shape. Furthermore, the number of the openings 56 to be provided is not limited to one, and a plurality of the openings 56 may be provided.

According to the fourth embodiment, since the coating film 52 covering the heat conductive member 50 is provided, as in the second embodiment, deformation of the heat conductive member 50 in the X and Y directions is suppressed. Therefore, a part of the heat conductive member 50 and the coating film 52 easily enters the opening 34 of the guide member 30. The opening 56 is provided in the portion of the coating film 52 positioned at the surface of the heat conductive member 50 on the side of the substrate 10. For this reason, as illustrated in FIGS. 12A to 12C, when the electronic device 70 is inserted, the heat conductive member 50 comes into contact with the electronic device 70 at the opening 56. Therefore, cooling performance for the electronic device 70 may be improved as compared with that in the second embodiment.

A size of the opening 56 provided in the coating film 52 is preferably 20% or more, more preferably 30% or more, still more preferably 40% or more of an area of the surface of the heat conductive member 50 on the side of the substrate 10 from a viewpoint of bringing the heat conductive member 50 into contact with the electronic device 70. On the other hand, when the opening 56 is too large, the effect of suppressing deformation of the heat conductive member 50 in the X and Y directions is weakened. Therefore, the size of the opening 56 is preferably 70% or less, more preferably 60% or less, still more preferably 50% or less of the area of the surface of the heat conductive member 50 on the side of the substrate 10.

Note that, in the fourth embodiment, in addition to the opening 56 in the surface of the heat conductive member 50 on the side of the substrate 10, the coating film 52 may have an opening 54 in the surface of the heat conductive member 50 on the side of the heat radiation member 20, as in the third embodiment.

Note that, also in the second to fourth embodiments, as in the modification of the first embodiment, a heat radiation member 20a may be provided instead of the heat radiation member 20.

Although the embodiments have been described in detail above, the embodiments are not limited to such specific embodiments, and various modifications and alternations may be made within the scope of the gist of the embodiments described in the claims.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A cooling module comprising:
a substrate;
a heat radiation member fixed to the substrate with a gap between the heat radiation member and the substrate;
a guide member that is disposed at a surface of the heat radiation member on a side of the substrate and that allows an electronic device to be inserted between the guide member and the substrate;
a fixing mechanism that fixes the guide member to the heat radiation member so as to be movable in a direction in which the substrate and the guide member face each other; and
a compressively deformable heat conductive member that is disposed between the heat radiation member and the guide member and overlaps with an opening provided in the guide member in a plan view.

2. The cooling module according to claim 1, wherein
the guide member includes a protrusion portion that protrudes toward the side of the substrate, a side surface of the protrusion portion on a side into which the electronic device is inserted is an inclined surface, and the opening is provided in a top surface of the protrusion portion.

3. The cooling module according to claim 2, wherein
the guide member has a recess portion coupled to the opening in a surface on a side of the heat radiation member, and the heat conductive member is provided in the recess portion and overlaps with the opening in a plan view.

4. The cooling module according to claim 1, wherein
the guide member is pushed up toward a side of the heat radiation member when the electronic device inserted between the substrate and the guide member comes into contact with the guide member, and the heat conductive member is compressively deformed when the guide member is pushed up toward the side of the heat radiation member.

5. The cooling module according to claim 1, wherein
the fixing mechanism includes a fixing member that fixes the guide member to the heat radiation member and an energizing member that is provided between the guide member and the heat radiation member and energizes the guide member toward the side of the substrate.

6. The cooling module according to claim 1, wherein
the heat conductive member is rubber to which a heat conductive filler is added.

7. The cooling module according to claim 1, further comprising:
a coating film that covers the heat conductive member.

8. The cooling module according to claim 7, wherein
the coating film has an opening in a surface of the heat conductive member on a side of the heat radiation member.

9. The cooling module according to claim 7, wherein
the coating film has an opening in a surface of the heat conductive member on the side of the substrate.

10. The cooling module according to claim 7, wherein
the heat conductive member is rubber to which a heat conductive filler is added, and the coating film is a polyethylene terephthalate film, a polytetrafluoroethylene film, or a stainless steel film.

11. The cooling module according to claim 1, wherein
the heat radiation member has a refrigerant flow path through which a refrigerant flows.

12. The cooling module according to claim 1, wherein the heat radiation member has a plurality of heat dissipation fins.
